(19) United States
(12) Patent Application Publication
(10) Pub. No.: US 2011/0127543 A1
(43) Pub. Date: Jun. 2, 2011

(54) SEMICONDUCTOR DEVICE

(75) Inventor: Kensuke AKIYOSHI, Fukuoka (JP)

(73) Assignee: KABUSHIKI KAISHA YASKAWA DENKI, Kitakyushu-shi (JP)

(21) Appl. No.: 12/898,715

(22) Filed: Oct. 6, 2010

(30) Foreign Application Priority Data
Dec. 1, 2009 (JP) 2009-273579

(51) Int. Cl. H01L 23/22; H01L 29/20; H01L 29/24

(52) U.S. Cl. 257/77; 257/687; 257/76; 257/E23.139; 257/E29.089; 257/E29.104

(57) ABSTRACT

A semiconductor device includes a substrate, a semiconductor element disposed on the main surface of the substrate and generating a heat of 200° C. or more, an enclosure surrounding the semiconductor element, and a liquid sealant containing a heat-resistant oil. The enclosure controls the flow of the sealant and seals the semiconductor element.

### CROSS REFERENCE TO RELATED APPLICATIONS

The present application claims priority to Japanese Patent Application No. 2009-273579, filed Dec. 1, 2009. The contents of this application are incorporated herein by reference in its entirety.

### BACKGROUND OF THE INVENTION

1. Field of the Invention

The present invention relates to sealing of a semiconductor element.

2. Discussion Of The Background

For example, Japanese Unexamined Patent Application Publication No. 6-112350 discloses a semiconductor device including a semiconductor element sealed with silicone gel on a substrate.

### SUMMARY OF THE INVENTION

According to one aspect of the present invention, there is provided a semiconductor device including a substrate having a main surface, a semiconductor element disposed on the main surface and generating a heat of 200° C. or more, an enclosure surrounding the semiconductor element, and a liquid sealant containing a heat-resistant oil. The enclosure controls the flow of the sealant and seals the semiconductor element.

According to another aspect of the present invention, a semiconductor device is provided which includes a substrate, a semiconductor element made of SiC or GaN, and a sealant sealing the semiconductor element. The sealant contains a liquid oil resistant to the heat generated by the semiconductor element.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a sectional view of a semiconductor device according to a first embodiment of the present invention; and

FIG. 2 is a sectional view of a semiconductor device according to a second embodiment of the present invention.

### DESCRIPTION OF THE EMBODIMENTS

Embodiments will now be described with reference to the accompanying drawings, wherein like reference numerals designate corresponding or identical elements throughout the various drawings.

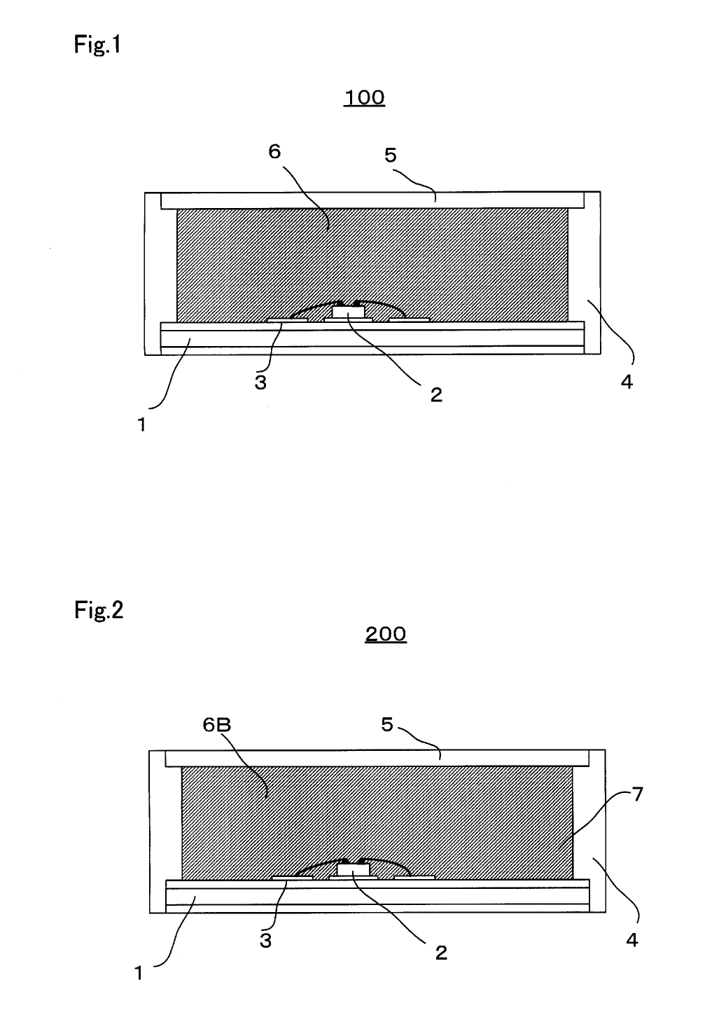

FIG. 1 is a sectional view of a semiconductor device 100 according to a first embodiment. The semiconductor device 100 includes a circuit substrate 1, a semiconductor element 2 disposed on a main surface of the circuit substrate 1, pads 3 electrically connected to the semiconductor element 2, an enclosure 4 (called a case 4 in the present embodiment) surrounding the semiconductor element 2 on the main surface of the circuit substrate 1, a cover 5 disposed on the enclosure 4, and a sealant 6 accommodated in the space defined by the circuit substrate 1, the enclosure 4 and the cover 5. The sealant 6 has fluidity, and the flow of the sealant 6 is controlled by the enclosure 4.

The semiconductor element 2 is made of SiC, GaN or the like and generates a heat of 200° C. or more.

The sealant 6 contains a heat-resistant liquid oil. Accordingly, the sealant can appropriately seal the semiconductor element 2 generating a heat of 200° C. or more. In addition, since a liquid oil is used as the sealant, thermal stress generated inside can be reduced.

A fluorocarbon oil GALDEN D40 produced by Solvay Solexis can be used as the sealant 6. A synthetic oil BARREL THERM 400 produced by Matsumura Oil may be used. Alternatively, a silicone oil BARREL SILICONE FLUID ST produced by Matsumura Oil may be used. While these liquid oils have been cited as examples of the sealant 6, it is to be understood that the sealant used in the invention is not limited to the cited examples, and that similar materials may be used within the scope and spirit of the invention.

Fluorocarbon oil has a heat resistance of about 250° C. If a fluorocarbon oil is used as the sealant 6, the semiconductor element can be operated at temperatures of almost 250° C. Synthetic oil has heat resistance of about 300° C. If a synthetic oil is used as the sealant 6, the semiconductor element can be operated at temperatures of almost 300° C. Silicone oil has heat resistance of about 400° C. If a silicone oil is used as the sealant 6, the semiconductor element can be operated at temperatures of almost 400° C.

Since the sealant 6 is bonded to none of the circuit substrate 1, the semiconductor element 2, the pads 3, the case 4 and the cover 5, thermal stress is not likely to occur due to the difference in thermal expansion coefficient. Consequently, the reliability of the semiconductor device can be increased.

In manufacture of the semiconductor device, first, a hybrid integrated circuit is prepared by mounting electronic components (not shown), such as a resistor and a capacitor, and a semiconductor element 2 on the pads 3 disposed on the circuit substrate 1 having a desired wiring pattern.

The circuit substrate 1 is fixed in the case 4 with, for example, an adhesive. Then, the case 4 is filled with the sealant 6 to seal the semiconductor element 2 and the electronic components. Further, the upper open end of the case 4 is closed with the cover 5. This operation is performed so that no air remains between the sealant 6 and the cover 5. The case 4 and the cover 5 are secured with an adhesive or an O ring therebetween, for example, by screwing.

FIG. 2 shows a sectional view of a semiconductor device 200 according to a second embodiment. In the description of the semiconductor device 200 of the second embodiment, the same parts or elements as in the first embodiment are designated by the same reference numerals, and duplicate description will be omitted.

The semiconductor device 200 of the second embodiment also includes a sealant 6B. The sealant 6B contains an insulating material 7. The insulating material 7 may be a powder of metal oxides such as silicon oxide and aluminium oxide, nitrides such as aluminium nitride and boron nitride, and hydroxides such as aluminium hydroxide and magnesium hydroxide. For example, a silicon oxide FB-74 produced by Denki Kagaku Kogyo may be used as the insulating material 7. The insulating material 7 is dispersed in the sealant 6B.

While these insulating materials have been cited as examples of the insulating material 7, it is to be understood that the insulating material used in the invention is not limited to the cited examples, and that similar materials can be used within the scope and spirit of the invention.

In the second embodiment, the same effect as in the first embodiment is produced and, in addition, the insulating material can form a thermal radiation path and impart incombustibility. Particularly in a semiconductor device generating a high temperature heat, the structure of the second embodiment can remarkably prevent the temperature increase of the semiconductor element.

Obviously, numerous modifications and variations of the present invention are possible in light of the above teachings. It is therefore to be understood that within the scope of the appended claims, the invention may be practiced otherwise than as specifically described herein.

What is claimed as new and is desired to be secured by Letters Patent of the United States is:

1. A semiconductor device comprising:
a substrate having a main surface;
a semiconductor element disposed on the main surface of the substrate, the semiconductor element generating a heat of 200° C. or more;
an enclosure surrounding the semiconductor element; and
a liquid sealant containing a heat-resistant oil whose flow is controlled by the enclosure, the sealant sealing the semiconductor element.

2. The semiconductor device according to claim 1, wherein the heat resistant oil is selected from the group consisting of fluorocarbon oils, synthetic oils, and silicone oils.

3. The semiconductor device according to claim 2, wherein the sealant further contains an insulating material dispersed therein.

4. The semiconductor device according to claim 3, further comprising a cover disposed on the enclosure so that a space is defined by the main surface of the substrate, the enclosure and the cover, wherein the sealant is accommodated in the space.

5. A semiconductor device comprising:
a substrate;
a semiconductor element made of SiC or GaN and disposed on the substrate, the semiconductor element generating a heat; and
a sealant sealing the semiconductor element, the sealant containing a liquid oil resistant to the heat.

6. The semiconductor device according to claim 5, further comprising an enclosure disposed on the substrate, the enclosure surrounding the sealant, wherein the sealant contains an insulating material dispersed therein.

7. The semiconductor device according to claim 6, wherein the liquid oil is selected from the group consisting of fluorocarbon oils, synthetic oils, and silicone oils.

8. The semiconductor device according to claim 7, further comprising a cover disposed on the enclosure so that a space is defined by the substrate, the enclosure and the cover, wherein the sealant is accommodated in the space.
